(19) United States
(12) Patent Application Publication
(10) Pub. No.: US 2018/0295742 A1
(43) Pub. Date: Oct. 11, 2018

(54) ORGANIC LIGHT EMITTING DEVICE AND FABRICATING METHOD THEREOF

(71) Applicant: BOE Technology Group Co., Ltd., Beijing (CN)

(72) Inventor: Xinwei GAO, Beijing (CN)

(21) Appl. No.: 15/820,037

(22) Filed: Nov. 21, 2017

(30) Foreign Application Priority Data
Apr. 5, 2017 (CN) 201710218069.5

(51) Int. Cl. H05K 7/20

(52) U.S. Cl. CPC H05K 7/2099; H05K 7/20963

(57) ABSTRACT

The present disclosure discloses an organic light emitting device and a fabricating method thereof. The organic light emitting device includes an organic light emitting display panel, a package cover plate disposed on the organic light emitting display panel, a heat dissipating adhesive layer disposed on the package cover plate, and a heat dissipating plate disposed on the heat dissipating adhesive layer, wherein the heat dissipating adhesive layer is filled with a plurality of micro heat pipes, and the micro heat pipes are used for dissipating heat generated by the organic light emitting panel.

### CROSS-REFERENCE TO RELATED APPLICATIONS

This application claims the priority to Chinese Patent Application No. 201710218069.5, filed on Apr. 5, 2017, the content of which is hereby incorporated by reference in its entirety.

### FIELD

The present disclosure relates to the technical field of displaying, in particular to an organic light emitting device and a fabricating method thereof.

### BACKGROUND

With the development of display technology, Organic Light Emitting Diode (OLED) has been one of the hotspots among today's flat panel display research; more and more Active Matrix Organic Light Emitting Diode (AMOLED) display panels enter the market. Compared to the traditional liquid crystal display, OLED is ultrathin and further has the advantages of good shock resistance, large viewing angle, short response time, good low temperature performance, high luminous efficiency and the like.

The OLED display technology with self-luminous characteristics adopts a very thin organic material coating as a light emitting layer, when there is current passing, the organic material may emit light to achieve the purpose of lighting or displaying. However, the Joule heat generated during the continuous operation of an OLED device accumulates to cause a problem that the organic luminescent material is crystallized and the cathode is peeled off, resulting in a decrease in the luminous efficiency and service life of the OLED device. In addition, the OLED device is highly influenced by temperature; when the temperature exceeds 50 degrees centigrade or higher, its life decay rate exponentially increases, so strict temperature control is particularly important to the service life of the OLED device. In the prior art, the service life and reliability of the OLED device are improved by adding a heat dissipating device at the periphery of the OLED device, but the method is subject to the thermal conductivity of the metal heat transfer material used and the heat dissipation effect is poor.

Therefore, it is an urgent problem to be solved by a person skilled in the art to effectively improve the heat dissipation effect of the OLED device and thereby improve the service life and reliability of the device.

### SUMMARY

An embodiment of the present disclosure provides an organic light emitting device, including an organic light emitting display panel, a package cover plate disposed on the organic light emitting display panel, a heat dissipating adhesive layer disposed on the package cover plate, and a heat dissipating plate disposed on the heat dissipating adhesive layer, wherein the heat dissipating adhesive layer is filled with a plurality of micro heat pipes; the micro heat pipes are used for dissipating heat generated by the organic light emitting panel.

An embodiment of the present disclosure provides a fabricating method of the organic light emitting device according to the embodiment of the present disclosure, and the method includes: forming an organic light emitting display panel through a patterning process; packaging the formed organic light emitting display panel with a package cover plate through a packaging process; forming a heat dissipating adhesive layer on the organic light emitting display panel packaged with the package cover plate, wherein the heat dissipating adhesive layer is filled with a plurality of micro heat pipes; forming a heat dissipating plate on the heat dissipating adhesive layer filled with the micro heat pipes; and curing the heat dissipating adhesive layer through a thermocuring process.

### BRIEF DESCRIPTION OF THE DRAWINGS

FIG. 1 is a schematic diagram of the structure of an organic light emitting device according to an embodiment of the present disclosure;

FIG. 2 is a schematic diagram of the structure of a micro heat pipe according to an embodiment of the present disclosure;

FIG. 3 is a schematic diagram of the heat dissipating principle of the micro heat pipes according to an embodiment of the present disclosure; and

FIG. 4 is a flow chart of a fabricating method of an organic light emitting device according to an embodiment of the present disclosure.

### DETAILED DESCRIPTION OF THE EMBODIMENTS

The specific implementations of the organic light emitting device and the fabricating method thereof according to embodiments of the present disclosure are described in detail with reference to the accompanying drawings.

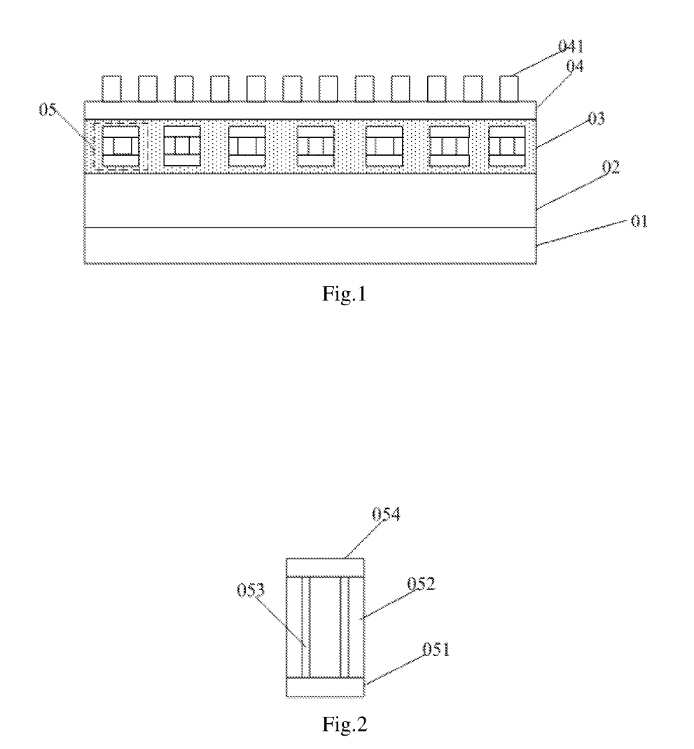

An embodiment of the present disclosure disclose an organic light emitting device, as shown in FIG. 1, including an organic light emitting display panel 01, a package cover plate 02 disposed on the organic light emitting display panel 01, a heat dissipating adhesive layer 03 disposed on the package cover plate 02, and a heat dissipating plate 04 disposed on the heat dissipating adhesive layer 03, wherein the heat dissipating adhesive layer 03 is filled with a plurality of micro heat pipes 05, and the micro heat pipes 05 are used for dissipating heat generated by the organic light emitting panel 01.

In the organic light emitting device according to the embodiment of the present disclosure, the heat dissipating adhesive layer is filled with the micro heat pipes, thus the organic light emitting display panel can be cooled by virtue of the micro heat pipes. Furthermore, the thermal conductivity of the micro heat pipes is greater than that of any of the known metal materials, so the use of the micro heat pipes can achieve a better heat dissipating effect. In addition, by using the combination of the micro heat pipes, the heat dissipating plate and the heat dissipating adhesive, the heat generated by the organic light emitting display panel can be better dissipated, thereby effectively improving the service life and reliability of OLED device.

In a specific implementation, in the organic light emitting device according to the embodiment of the present disclosure, as shown in FIG. 2, each of the micro heat pipes may include an evaporating end 051, a heat insulating section 052, a capillary wall 053 and a condensing end 054. The evaporating end 051 is deposited at one side, close to the package cover plate, inside the heat dissipating adhesive layer; the condensing end 054 is deposited at the other side, opposite to the evaporating end, inside the heat dissipating adhesive layer; the heat insulating section 052 is deposited between the evaporating end 051 and the condensing end 054 and configured to support the evaporating end 051 and the condensing end 054 to form a tubular micro heat pipe; the capillary wall 053 is deposited on the inner wall of the tubular micro heat pipe.

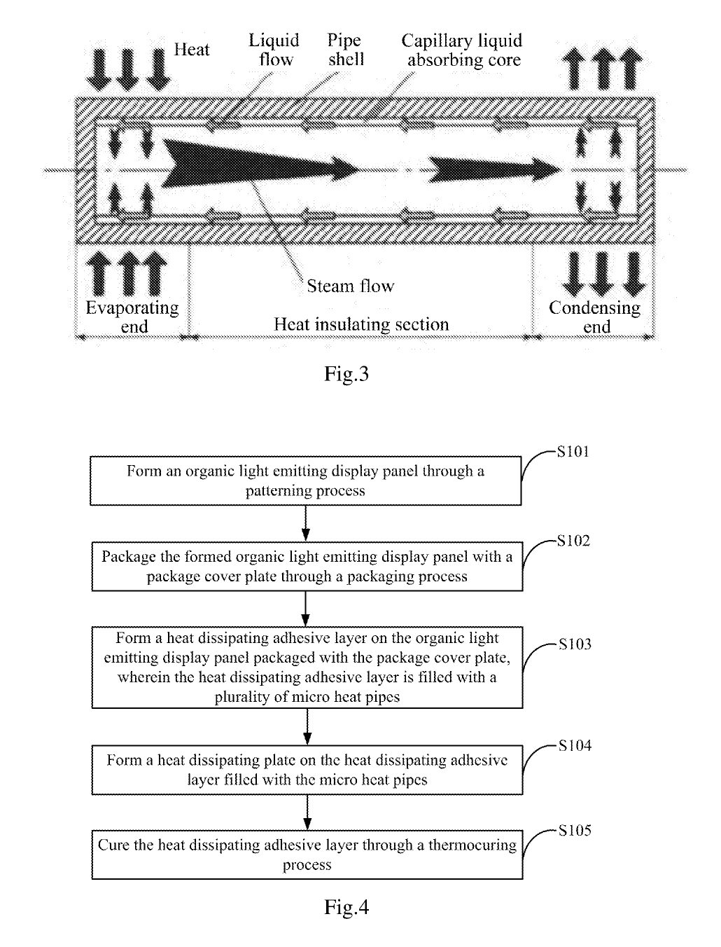

Specifically, in the organic light emitting device according to the embodiment of the present disclosure, each of the micro heat pipes mainly includes an evaporating end, a heat insulating section, a capillary wall and a condensing end. As shown in FIG. 3, the heat dissipation principle of the micro heat pipes is as follows: heat is absorbed through the evaporating end, the hollow tube core of the tubular micro heat pipe is filled with the heat-transfer medium, and the heat can be converted into a steam flow to be conveyed to the condensing end for dissipation; wherein a capillary liquid absorbing core arranged in the capillary wall can also convey a liquid flow in the steam flow, and after being conveyed to the evaporating end, the liquid flow is evaporated into the steam flow through heat absorbed by the evaporating end and then further conveyed to the condensing end for dissipation. In addition, the heat-transfer medium within the tube core of the micro heat pipe may be any of pure water, methanol or ethanol and can be selected according to actual needs in practice, and thus will not be limited herein.

In a specific implementation, in the organic light emitting device according to the embodiment of the present disclosure, a plurality of micro heat pipes inside the heat dissipating adhesive layer are arranged in matrix, so that the heat generated in respective regions of the organic light emitting display panel is dissipated out through the micro heat pipes in corresponding regions in a timely manner. Of course, in real application, for different types of organic light emitting display panels whose heat generated by their different areas is different, the distribution of the micro heat pipes can be adjusted accordingly, so that heat generated by the organic light emitting display panel can be dissipated out as soon as possible targetedly, and thus the service life and reliability of the organic light emitting device can be effectively improved.

In a specific implementation, the organic light emitting device according to the embodiment of the present disclosure may further include a heat dissipating layer deposited between the organic light emitting display panel and the package cover plate. Specifically, in order to improve the heat dissipation capability of the organic light emitting device, a heat dissipating layer made of a heat dissipating material may be added between the organic light emitting display panel and the package cover plate, so that the heat dissipation efficiency of the organic light emitting device can be further improved.

In a specific implementation, the above-described organic light emitting device according to the embodiment of the present disclosure, in order to dissipate out the heat generated by the organic light emitting display panel, the material of the package cover plate may be a metal or glass having thermal conductivity, and of course, also may be other materials meeting the design requirements, and thus will not be limited herein.

In a specific implementation, in the organic light emitting device according to the embodiment of the present disclosure, as shown in FIG. 1, the heat dissipating plate 04 may include a plurality of cooling fins 041 arranged in matrix. In order to quickly dissipate out the heat generated by the organic light emitting panel, it is possible to perform rapid heat dissipation by arranging a plurality of cooling fins in matrix on the heat dissipating plate.

Based on the same inventive concept, an embodiment of the present disclosure provides a fabricating method of the organic light emitting device according to the embodiment of the present disclosure and as shown in FIG. 4, the method includes the following steps.

Step S101 is to form an organic light emitting display panel through a patterning process.

Step S102 is to package the formed organic light emitting display panel with a package cover plate through a packaging process.

Step S103 is to form a heat dissipating adhesive layer on the organic light emitting display panel packaged with the package cover plate, wherein the heat dissipating adhesive layer is filled with a plurality of micro heat pipes.

Step S104 is to form a heat dissipating plate on the heat dissipating adhesive layer filled with the micro heat pipes.

Step S105 is to cure the heat dissipating adhesive layer through a thermocuring process.

In the fabricating method of the organic light emitting device according to the embodiment of the present disclosure, by filling the heat dissipating adhesive layer with the micro heat pipes, the organic light emitting display panel can be cooled by virtue of the micro heat pipes. Furthermore, the thermal conductivity of the micro heat pipes is better than that of any of the known metal materials, so the use of the micro heat pipes can achieve a better heat dissipating effect. In addition, by using the combination of the micro heat pipes, the heat dissipating plate and the heat dissipating adhesive, the heat generated by the organic light emitting display panel can be better dissipated, thereby effectively improving the service life and reliability of OLED device.

In a specific implementation, in the fabricating method according to the embodiment of the present disclosure, the step S103 may include: through a screen printing process or a slit coating process, coating a heat dissipating adhesive on the organic light emitting display panel packaged with the package cover plate to form the heat dissipating adhesive layer. Specifically, the heat dissipating adhesive layer may be made by a screen printing process or a slit coating process, and of course may also be made by using other film-forming processes satisfying the design requirements of the present disclosure, and thus it will not be limited herein. After forming the heat dissipating adhesive layer, it is also necessary to place a plurality of micro heat pipes in the formed heat dissipating adhesive layer, thereby forming a heat dissipating adhesive layer filled with the micro-heat pipes. In order to dissipate the heat generated by the organic light emitting display panel, the evaporating ends of the micro heat pipes need to be deposited at one side, close to the package cover plate, inside the heat dissipating adhesive layer, and in this way, the heat generated by the organic light emitting display panel can be absorbed quickly and further dissipated out through the micro heat pipes.

The embodiments of the present disclosure provide an organic light emitting device and a fabricating method thereof. The organic light emitting device includes an organic light emitting display panel, a package cover plate disposed on the organic light emitting display panel, a heat dissipating adhesive layer disposed on the package cover plate, and a heat dissipating plate disposed on the heat dissipating adhesive layer, wherein the heat dissipating adhesive layer is filled with a plurality of micro heat pipes, and the micro heat pipes are used for dissipating heat generated by the organic light emitting panel. By filling the heat dissipating adhesive layer with the micro heat pipes in such a way, the organic light emitting display panel is cooled by virtue of the micro heat pipes. Furthermore, the thermal conductivity of the micro heat pipes is better than that of any of the known metal materials, so the use of micro heat pipes can achieve better heat dissipating effect. In addition, by using the combination of the micro heat pipes, the heat dissipating plate and the heat dissipating adhesive, the heat generated by the organic light emitting display panel can be better dissipated, thereby effectively improving the service life and reliability of OLED device.

It will be apparent to those skilled in the art that various changes and modifications can be made in the present disclosure without departing from the spirit and scope of the present disclosure. In this manner, the present disclosure is intended to incorporate such modifications and variations if the modifications and variations of the present disclosure are within the scope of the appended claims of the present disclosure and the equivalents thereof.

1. An organic light emitting device, comprising:
an organic light emitting display panel, a package cover plate disposed on the organic light emitting display panel, a heat dissipating adhesive layer disposed on the package cover plate, and a heat dissipating plate disposed on the heat dissipating adhesive layer, wherein:
the heat dissipating adhesive layer is filled with a plurality of micro heat pipes;
the micro heat pipes are used for dissipating heat generated by the organic light emitting panel.

2. The organic light emitting device according to claim 1, wherein each of the micro heat pipes comprises an evaporating end, a heat insulating section, a capillary wall and a condensing end; wherein:
the evaporating end is deposited at one side, close to the package cover plate, inside the heat dissipating adhesive layer;
the condensing end is deposited at the other side, opposite to the evaporating end, inside the heat dissipating adhesive layer;
the heat insulating section is deposited between the evaporating end and the condensing end and configured to support the evaporating end and the condensing end to form a tubular micro heat pipe;
the capillary wall is deposited on the inner wall of the tubular micro heat pipe.

3. The organic light emitting device according to claim 2, wherein each of the micro heat pipes is filled with a heat-transfer medium.

4. The organic light emitting device according to claim 3, wherein the heat-transfer medium is any of pure water, methanol or ethanol.

5. The organic light emitting device according to claim 1, wherein the plurality of micro heat pipes are arranged in matrix in the heat dissipating adhesive layer.

6. The organic light emitting device according to claim 1, further comprising: a heat dissipating layer deposited between the organic light emitting display panel and the package cover plate.

7. The organic light emitting device according to claim 1, wherein a material of the package cover plate is metal or glass.

8. The organic light emitting device according to claim 1, wherein the heat dissipating plate comprises a plurality of cooling fins arranged in matrix.

9. A fabricating method of the organic light emitting device according to claim 1, comprising:
forming an organic light emitting display panel through a patterning process;
packaging the formed organic light emitting display panel with a package cover plate through a packaging process;
forming a heat dissipating adhesive layer on the organic light emitting display panel packaged with the package cover plate, wherein the heat dissipating adhesive layer is filled with a plurality of micro heat pipes;
forming a heat dissipating plate on the heat dissipating adhesive layer filled with the micro heat pipes; and
curing the heat dissipating adhesive layer through a thermocuring process.

10. The method according to claim 9, wherein forming the heat dissipating adhesive layer on the organic light emitting display panel packaged with the package cover plate comprises:
coating a heat dissipating adhesive on the organic light emitting display panel packaged with the package cover plate to form the heat dissipating adhesive layer, through a screen printing process or a slit coating process.

11. The method according to claim 10, further comprising:
placing the plurality of micro heat pipes in the formed heat dissipating adhesive layer, wherein the evaporating end of each of the micro heat pipes is deposited at one side, close to the package cover plate, inside the heat dissipating adhesive layer.
